(19) United States
(12) Patent Application Publication
(10) Pub. No.: US 2026/0155785 A1
(43) Pub. Date: Jun. 4, 2026

(54) HIGH PERFORMANCE CMOS SHOOTING INTEGRATOR

(71) Applicant: Hamad Bin Khalifa University (HBKU), Doha (QA)

(72) Inventor: Bo Wang, Doha (QA)

(21) Appl. No.: 19/395,485

(22) Filed: Nov. 20, 2025

Related U.S. Application Data
(60) Provisional application No. 63/726,820, filed on Dec. 2, 2024.

(51) Int. Cl. H03F 1/02; H03F 3/45

(52) U.S. Cl. CPC H03F 1/0205; H03F 3/45475; H03F 2200/264; H03F 2203/45151; H03F 2203/45616

(57) ABSTRACT

The present disclosure provides for a high performance CMOS shooting integrator. According to one aspect of the present disclosure a high performance CMOS shooting integrator. According to a second aspect of the present disclosure a method of using a high performance CMOS shooting integrator.

### PRIORITY CLAIM AND CROSS-REFERENCE TO RELATED APPLICATIONS

This application claims priority to and the benefit of U.S. Provisional Patent App. No. 63/726,820 filed Dec. 2, 2024, titled HIGH PERFORMANCE CMOS SHOOTING INTEGRATOR, the contents of which are incorporated by reference herein in their entirety and relied upon.

### BACKGROUND

Energy efficiency is a critical concern in data converters for sensing and instrumentation applications. In high-resolution switched capacitor (SC) data converters, especially delta-sigma converters, the analog integrators typically consume most of the system power due to the need of driving large sampling and integration capacitors to meet the noise and speed requirements. Recent advancements have focused on replacing traditional operational amplifiers (op-amps) in integrators with more efficient alternatives, such as dynamic amplifiers, ring amplifiers [1], floating inverter amplifiers [2], or other amplifier types together with topological techniques like zoom [3], integrator slicing [4], pseudo-pseudo-differential [5], etc. These devices and methods have improved data converter efficiency substantially. Despite these advancements, a fundamental tradeoff between noise, power, speed, and accuracy remains in integrator designs. Using an integrator with a virtual ground reference buffer can reduce its effective capacitive load and therefore reduce power consumption [6], but noise and nonlinearity introduced by the buffer remain problematic. The zero-crossing-based (ZCB) integrator can entirely isolate its capacitive load from the driving circuit [7]. However, even with overshoot correction, a large settling error induced by a comparator delay restricts the use of ZCB only in moderate-resolution analog-to-digital converters (ADCs). Integrators with capacitor stacking and buffering (CSB) inherit the efficiency of passive integrators [8], but its signal gain is close to unity. It is rather challenging, although feasible, to perform signal scaling that is often needed in delta-sigma modulator, or amplification in multiplying digital-to-analog converter (MDAC) needed in pipelined analog-to-digital converters (ADC). The CSB integrator is also sensitive to circuit parasitic.

As such, there is a need for CMOS integrator with higher performance.

### SUMMARY

In part, in one aspect, the present disclosure relates to systems and methods for realizing a high-performance CMOS shooting integrator.

In one non-limiting aspect, the present disclosure describes an exemplary embodiment of a high-performance CMOS shooting integrator.

In another second non-limiting aspect, the present disclosure describes an exemplary embodiment of a method of using a high-performance CMOS shooting integrator.

Additional features and advantages are described in, and will be apparent from, the following Detailed Description and the Figures. The features and advantages described herein are not all-inclusive and, in particular, many additional features and advantages will be apparent to one of ordinary skill in the art in view of the figures and description. In addition, any particular embodiment does not have to have all of the advantages listed herein and it is expressly contemplated to claim individual advantageous embodiments separately. Moreover, it should be noted that the language used in the specification has been selected principally for readability and instructional purposes, and not to limit the scope of the inventive subject matter.

### BRIEF DESCRIPTION OF THE DRAWINGS

FIGS. 1-4 show the simplified diagrams of prior art switched-capacitor integrators.

FIGS. 5A and 5B show circuit diagrams of a high-performance CMOS shooting integrator according to an example embodiment of the present disclosure.

FIG. 6 shows an example frequency response of the amplifier used in a high-performance CMOS shooting integrator according to an example embodiment of the present disclosure.

FIG. 7 shows signal waveforms at critical nodes of a high-performance CMOS shooting integrator at sampling and integration phases according to an example embodiment of the present disclosure.

FIG. 8 shows a settling behavior of a high-performance CMOS shooting integrator according to an example embodiment of the present disclosure.

FIG. 9 shows a noise model of a high-performance CMOS shooting integrator according to an example embodiment of the present disclosure.

FIG. 10 shows a circuit diagram of a pseudo-differential implementation of a high-performance CMOS shooting integrator with a passive common mode cancellation scheme according to one embodiment of the present invention.

FIG. 11 shows an example implementation of an amplifier used in a high-performance CMOS shooting integrator according to an example embodiment of the present disclosure.

### DETAILED DESCRIPTION

The present disclosure generally relates to a high-performance CMOS shooting integrator. Various embodiments may include a switched capacitor (SC) shooting integrator utilizing an uncompensated feedback loop and a barrier resistor to achieve accurate charge transfer. In various embodiments, a power consumption of an error amplifier in a high-performance CMOS shooting integrator as disclosed herein may be independent of sampling and/or integration capacitor sizes and/or an integrator settling speed. In various embodiments, a high-performance CMOS shooting integrator as disclosed herein may be subject to only a half-normal noise distribution thereby reducing a noise power of an integrator.

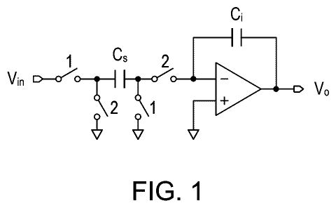

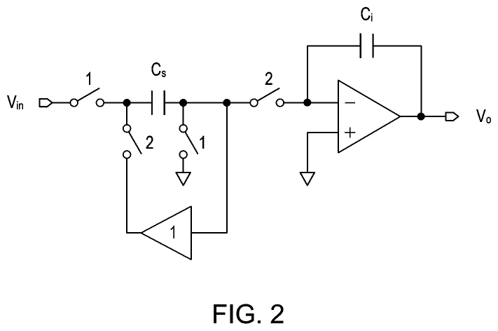

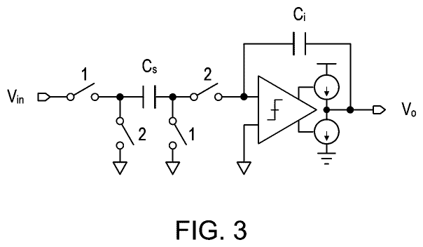

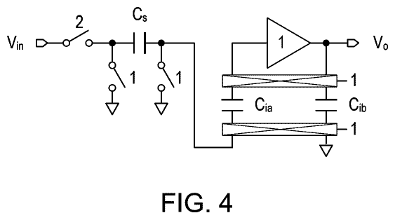

FIG. 1, FIG. 2, FIG. 3, and FIG. 4 depict various prior art embodiments of switched-capacitor (SC) integrators.

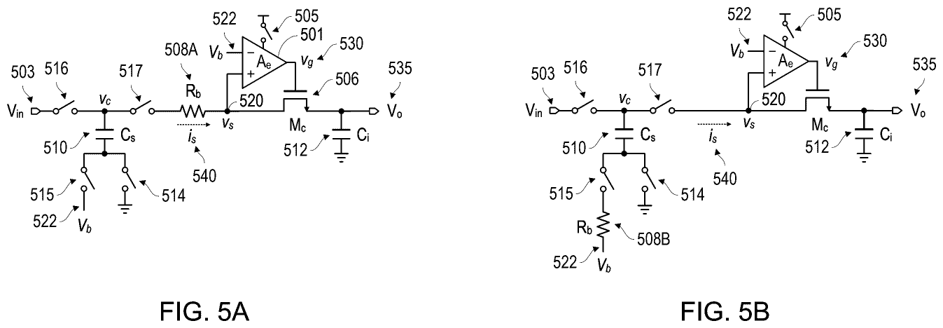

FIG. 5A and FIG. 5B show a high-performance CMOS shooting integrator according to an example embodiment of the present disclosure. A high-performance CMOS shooting integrator may include an error amplifier Aₑ 501. A switch 505 may provide or restrict power to the error amplifier 501. A high-performance CMOS shooting integrator may also include a control transistor M_{c} 506, a barrier resistor R_{b} 508A, a sampling capacitor Cₛ 510, an integration capacitor Cᵢ 512, and/or various switches 514-517 controlled by two non-overlapping clock phases. In various embodiments, such as the example embodiment of FIG. 5A, the barrier resistor R_{b} 508A may be in communication with a node vₛ 520. In other embodiments, such as the example embodiment of FIG. 5B, the barrier resistor R_{b} 508B may be in communication with a node V_{b} 522. An integrator performance may be invariant to an either placement of a barrier resistor. The integration capacitor Cᵢ 512 is referenced to ground or a common mode voltage rather than being connected around a virtual ground forcing or detection amplifier, such as in embodiments of FIG. 1 and FIG. 2. In FIG. 5A and FIG. 5B, during a sampling phase, switches 514, 516 are closed and switches 505, 515, 517 are open. During a sampling phase, an input voltage Vᵢₙ 503 is sampled at a first node of the sampling capacitor Cₛ 510. In some embodiments, during an integration phase, switches 514, 516 are open and switches 505, 515, 517 are closed. As such, a second node of the sampling capacitor Cₛ 510 is set to a bias voltage V_{b}, with the circuit nodes v_{c} and vₛ boosted to Vᵢₙ+V_{b}, correspondingly. In some embodiments, the control transistor M_{c} 506 presents a small gate capacitance as a load to the error amplifier Aₑ 501. During an integration phase, the error amplifier Aₑ 501 is powered and drives the load to an amplifier output voltage v_{g} 530, turning on the control transistor M_{c} 506 and triggering a unidirectional charge transfer from Cₛ 510 to Cᵢ 512 via M_{c} 506. This charge transfer may be called a “shooting” herein. In most embodiments, a voltage at the node vₛ 520 is higher than an output voltage Vₒ 535 to enable the unidirectional charge transfer from Cₛ 510 to Cᵢ 512. In FIG. 5A, as a current iₛ 540 increases, a voltage drop iₛ·R_{b} across the barrier resistor 508A reduces vₛ 520. In many embodiments, if vₛ is less than V_{b}, namely iₛ 540 greater than (Vᵢₙ−∫iₛ dt/Cs)/Rb, v_{g} will start to reduce after a short delay due to a phase shift of amplifier Aₑ. Within such a rise-fall cycle of v_{g}, a small amount of charge transfers from the sampling capacitor Cₛ into the integration capacitor Cᵢ. A decrease in v_{g} and iₛ then brings vₛ above V_{b}, the above charge transfer process repeats. When Aₑ is an uncompensated two-stage or multi-stage op-amp, by satisfying the Barkhausen stability criterion intentionally by design, the integrator will oscillate. In various embodiments, a discharge of the sampling capacitor Cₛ into the integration capacitor Cᵢ will dampen the oscillation. Effectively, vₛ behaves as an oscillating virtual ground. The charge transfer from the sampling capacitor Cₛ into the integration capacitor Cᵢ repeats until v_{c}, vₛ, and V_{b} are approximately equal and Vₒ at sampling cycle n is approximately equal to Vₒ[n−1]+Vᵢₙ·Cₛ/Cᵢ. In various embodiments, the control transistor M_{c} enters a weak inversion region and the integration completes after a short period of linear settling. In some embodiments, a duration of the integration may depend on a resolution requirement.

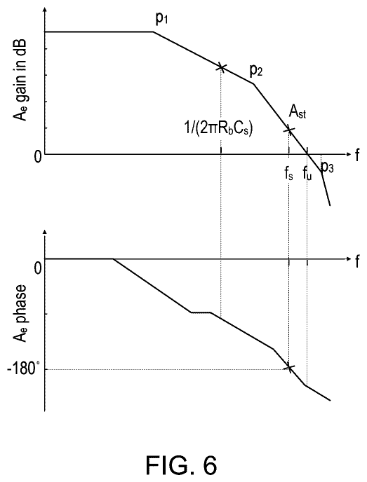

FIG. 6 shows an example frequency response of the error amplifier used in a high-performance CMOS shooting integrator according to an example embodiment of the present disclosure. In FIG. 6, vₛ oscillates at a frequency fₛ when a phase shift of Aₑ reaches −180°. In FIG. 6, p₁ is a dominant pole of Aₑ, p₂ is an in-band non-dominant pole of Aₑ, and p₃ is a first pole of Aₑ outside a unity gain bandwidth. Oscillations may stop once the Barkhausen's criteria Aₛₜ·g_{mc}·R_{b}≥1 no longer holds due to a decreased transconductance g_{mc} of M_{c} as more charge transfers to Cᵢ, with Aₛₜ being the error amplifier's open-loop gain when its phase shift is −180°, g_{mc} being the transconductance of M_{c}.

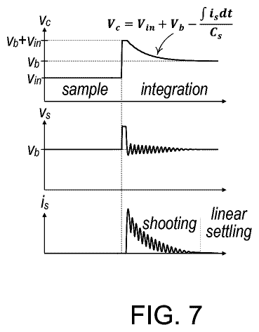

FIG. 7 shows some critical signal waveforms of a high-performance CMOS shooting integrator during the sampling and integration phases according to an example embodiment of the present disclosure. During operation, vₛ contains three signal components: a DC content, a high frequency content at frequency fₛ, and a low frequency signal decays exponentially at a time constant of R_{b}Cₛ for v_{c} to settle to V_{b}. For the integrator output Vₒ, its mathematical expression is Vₒ=∫iₛdt/Cᵢ, and it follows the settling envelope of v_{c}, which is independent of the speed of Aₑ.

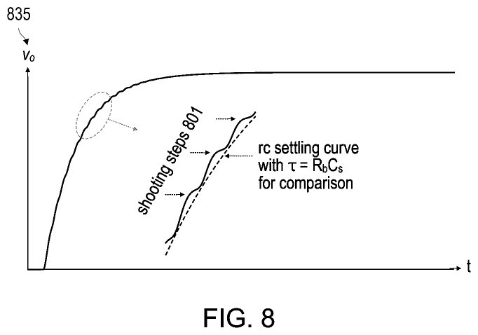

FIG. 8 shows a settling behavior of a high-performance CMOS shooting integrator according to an example embodiment of the present disclosure. The embodiment of FIG. 8 shows a high-performance CMOS shooting integrator output voltage Vₒ 835 over time. Shooting steps 801 indicate a transfer of electrical charge from a sampling capacitor Cₛ to an integration capacitor Cᵢ. In various embodiments, an error amplifier Aₑ of a high-performance CMOS shooting integrator may consume a small electrical power to drive an fF-level load to maintain its unity-gain frequency fᵤ above 1/(2πR_{b}Cₛ). At an end of an integration process, Aₑ handles a near-DC residue error. At an end of an integration process, a gain-induced static settling error of the amplifier Aₑ is inversely proportional to a DC gain of the amplifier Aₑ. One can prevent Aₑ from entering its slew-limited region via R_{b} and M_{c} sizing. Overall, this integrator can achieve accurate charge transfer without dynamic loop compensation as in ring-amp based integrator [1] nor perform overshoot correction as in ZCB integrators [7]. In various embodiments, the amplifier Aₑ may be independent of a sizing of a sampling capacitor Cₛ, a sizing of an integration capacitor Cᵢ, and/or an integrator settling speed. Except for its DC gain and pole placements, analog metrics like linearity, output swing, output common mode level, etc., are not of concern.

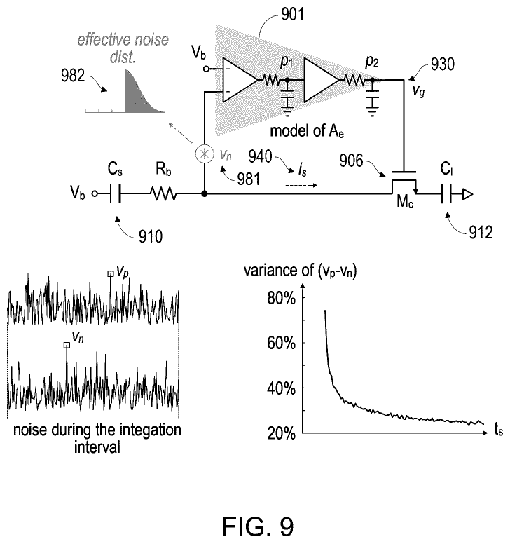

FIG. 9 shows a noise model of a high-performance CMOS shooting integrator according to an example embodiment of the present disclosure. In some embodiments, a control transistor of a high-performance CMOS shooting integrator, for example the control transistor M_{c} 906, may be near an off state when the integrator has settled. In this case, noise present at a drain of the control transistor may have minimal impact on an integrator output voltage Vₒ. In some embodiments, only circuit noise that induces positive changes to an amplifier output v_{g} 930 may increase a current iₛ 940, thus triggering noise charge flow. Therefore, an undesirable noise vₙ 981 may follow a half-normal distribution 982, when referenced a non-inverting input of amplifier Aₑ 901. Such a half-normal distribution of vₙ may include only about 36% (i.e., 1-2/π) of the amplifier's inherent noise power. In various embodiments, a noise charge may be supplied solely by a sampling capacitor Cₛ 910. Therefore, voltages v_{c}, vₛ and v_{g} may drop as more noise charge accumulates in an integration capacitor Cᵢ 912. Therefore, the integrator will be mainly affected by the largest amplitude of the noise vₙ experienced during integration. Therefore, in a differential or pseudo-differential implementation, both the positive and negative paths track their respective largest noise amplitude, which can get partially cancel out (subtract) during common mode cancellation. While power consumption of amplifier Aₑ is small, in various embodiments about 75% of a noise power of the amplifier Aₑ may be suppressed given a sufficient integration time. Residue low-frequency noise can be further suppressed by chopping between the two paths in a differential or pseudo-differential implementation.

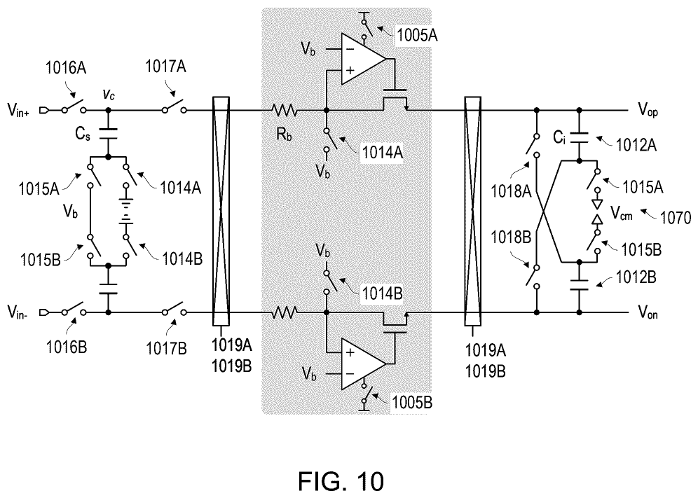

FIG. 10 shows a circuit diagram of a pseudo-differential implementation of a high-performance CMOS shooting integrator with a passive common mode cancellation scheme according to one embodiment of the present invention. In various embodiments, during a sampling phase, switches 1014A, 1014B, 1016A, 1016B, 1018A, 1018B are closed and switches 1005A, 1005B, 1015A, 1015B, 1017A, 1017B are open. In some embodiments, during an integration phase, switches 1014A, 1014B, 1016A, 1016B, 1018A, 1018B are open and switches 1005A, 1005B, 1015A, 1015B, 1017A, 1017B are closed. A first integration capacitor 1012A and a second integration capacitor 1012B are referenced to a common-mode voltage V_{cm} 1070. After each integration (during sampling), the first integration capacitor 1012A and the second integration capacitor 1012B are cross-connected by closing switches 1018A, 1018B to cancel an integrated input common-mode content. The upper path and lower path are chopped by choppers 1019A, 1019B to suppress low-frequency noise.

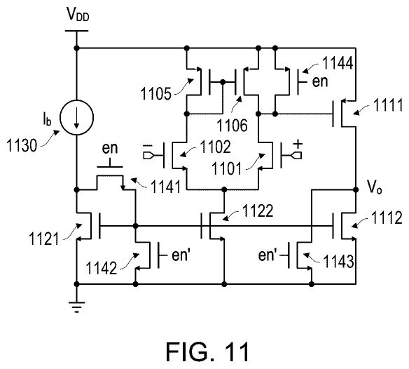

FIG. 11 shows an example implementation of an amplifier, such as an error amplifier, used in a high-performance CMOS shooting integrator according to an example embodiment of the present disclosure. An amplifier in a high-performance CMOS shooting integrator, such as the amplifier of FIG. 11, may be a two-stage operational amplifier without frequency compensation. In the amplifier of FIG. 11, a first amplification stage may include an NMOS differential pair 1101, 1102. In some embodiments, a PMOS current mirror, including PMOS transistors 1105, 1106, may load the first amplification stage. In various embodiments, a second amplification stage may include a PMOS input transistor 1111 with an NMOS load 1112. In various embodiments, a current mirror including transistors 1121, 1122 may mirror a bias current I_{b} 1130 to the first amplification stage. Various transistors 1141, 1142, 1143, 1144 enable or disable the amplifier according to complementary control signals en and en′. In some embodiments, complementary control signals en and en′ may be produced externally. In other embodiments, complementary control signals en and en′ may be produced internally with an inverter, for example.

References cited: [1] B. Hershberg et al., “Ring Amplifiers for Switched-Capacitor Circuits,” ISSCC, pp. 460-462, 2012; [2] Y. Liu et al., “A 4.96 μW 15 b Self-Timed Dynamic-Amplifier-Based Incremental Zoom ADC,” ISSCC, pp. 170-172, Feb. 2022; [3] L. Jie et al., “A 0.014 mm2 10 kHz-BW Zoom-Incremental-Counting ADC Achieving 103 dB SNDR and 100 dB Full-Scale CMRR,” ISSCC, pp. 1-3, Feb. 2022; [4] P. Vogelmann et al., “A 1.1 mW 200 kS/s incremental ΔΣ ADC with a DR of 91.5 dB using integrator slicing for dynamic power reduction,” ISSCC, pp. 236-238, Feb. 2018; [5] C. Y. Lee et al., “A 0.0375 mm2 203.5 μW 108.8 dB DR DT Single-Loop DSM Audio ADC Using a Single-Ended Ring-Amplifier-Based Integrator in 180 nm CMOS,” ISSCC, pp. 412-414, Feb. 2022; [6] H. H. Boo et al., “A 12b 250 MS/S pipelined ADC with virtual ground reference buffers,” ISSCC, pp. 1-3, Feb. 2015; [7] H.-S. Lee et al., “Zero-Crossing-Based Ultra-Low-Power A/D Converters,” Proc. IEEE, vol. 98, no. 2, pp. 315-332, Feb. 2010; [8] J. Liu et al., “A 250 kHz-BW 93 dB-SNDR 4th-Order Noise-Shaping SAR Using Capacitor Stacking and Dynamic Buffering,” ISSCC, pp. 369-371, Feb. 2021; [9] M. A. Mokhtar et al., “A 40 kS/s Calibration-Free Incremental ΔΣ ADC Achieving 104 dB DR and 105.7 dB SFDR,” ESSCIRC, pp. 401-404, Sept. 2023; [10] J.-S. Huang et al., “A Multistep Multistage Fifth-Order Incremental Delta Sigma Analog-to-Digital Converter for Sensor Interfaces,” JSSC, vol. 58, no. 10, pp. 2733-2744, Oct. 2023; and [11] C. Chen et al., “A 1V 14b Self-Timed Zero-Crossing-Based Incremental ΔΣ ADC,” ISSCC, pp. 274-275, Feb. 2013.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. An integrator circuit comprising:
an amplifier, wherein an inverting input of the amplifier is in electrical communication with an electrical bias voltage;
a first switch in electrical communication with a power supply and a power rail of the amplifier;
an NMOS transistor, wherein a gate terminal of the NMOS transistor is in electrical communication with an output terminal of the amplifier and wherein a drain terminal of the NMOS transistor is in electrical communication with a non-inverting input of the amplifier;
an integration capacitor in electrical communication with a source terminal of the NMOS transistor and a common node;
a resistor in electrical communication with the non-inverting input of the amplifier and a second switch;
a sampling capacitor comprising a first terminal and a second terminal, wherein the first terminal is in electrical communication with the second switch and a third switch, and wherein the second terminal is in electrical communication with a fourth switch and a fifth switch.

2. The integrator of claim 1, wherein the resistor is placed between the electrical bias voltage and the second switch.

3. The integrator of claim 1, wherein the resistor is placed between the second switch and the sampling capacitor.

4. The integrator of claim 1, wherein the resistor is placed between a V_{c} node and the fourth switch.

5. The integrator of claim 1, 2, 3, 4, wherein the resistor is implemented using metal resistor, poly resistor, or MOS transistor.

6. The integrator of claim 1, 2, 3, 4, 5, wherein the resistor is programmable.

7. The integrator of claim 1, wherein the sampling and integration capacitors are programmable.

8. The integrator of claim 1, wherein an electrical bias voltage V_{b} is one of constant or be time-varying or be programmable.

9. The integrator of claim 1, wherein the NMOS transistor is implemented using PMOS, and wherein an input polarity of the amplifier swaps to make a circuit function.

10. The integrator of claim 1 and 9, wherein the NMOS or PMOS transistor is programmable.

11. The integrator of claim 1, wherein for the claim the amplifier is implemented using a two-stage or multiple-stage topology.

12. The integrator of claim 1, the first, second, third, fourth or fifth switches are implemented using at least one of NMOS, PMOS, or CMOS transmission gate.

13. The integrator of claim 1, wherein the first switch is to enable or disable the amplifier bias current rather than power rail.
